(19) United States
(12) Patent Application Publication
(10) Pub. No.: US 2015/0010703 A1
(43) Pub. Date: Jan. 8, 2015

(54) Spin on Hard-Mask Material

(71) Applicant: The University of Birmingham, Birmingham (GB)

(72) Inventors: Andreas Frommhold, Gera (DE); Alex Robinson, Birmingham (GB); Jedsada Manyam, Maesod (TH)

(21) Appl. No.: 14/377,691

(22) PCT Filed: Jan. 31, 2013
(86) PCT No.: PCT/GB2013/050219

§ 371 Date: Aug. 8, 2014

Related U.S. Application Data
(60) Provisional application No. 61/597,710, filed on Feb. 10, 2012.

(51) Int. Cl. C09D 161/14; B05D 3/02; H01L 21/308; B05D 1/00

(52) U.S. Cl. CPC C09D 161/14; B05D 1/005; B05D 3/02; H01L 21/3081; H01L 21/3086
USPC 427/240; 524/594

(57) ABSTRACT

Disclosed and claimed herein is a composition for forming a spin-on hard-mask, having a fullerene derivative and a crosslinking agent. Further disclosed is a process for forming a hard-mask.

### FIELD OF THE INVENTION

The present application for patent is in the field of imaging for semiconductor manufacturing and more specifically is in the field of etch masking using spin-on formulations.

### BACKGROUND

Minimum feature sizes of semiconductor devices continue to shrink to enable increasing device densities. One method of achieving such high density patterning is to use thin photoresist films to mitigate problems such pattern collapse of high aspect-ratio resist features upon development. One possible solution to the problem involves using a high-resolution, high sensitivity and high etch durability fullerene resist. However, even though the aspect ratios produced by such resists may be as high as 5:1, the overall etch depth is limited significantly by the usable resist thickness.

A multilayer hard-mask stack can allow a further increase of the aspect ratio of the etched image. Such methods may use a thick amorphous carbon, deposited in-vacuo by chemical vapor deposition, which is then coated with a thin-silicon rich layer. A thin photoresist film is then sufficient to pattern the silicon-rich layer; thus avoiding pattern collapse. The silicon-rich layer is in-turn used as a hard-mask to pattern the carbon, giving a high aspect ratio carbon pattern suitable for providing a mask for etching the silicon wafer. By alternating from silicon to carbon rich materials and vice versa optimization of the overall etch selectivities of various substrates can be accomplished.

In recent years, vapor deposited materials have been replaced with spin-on etch masks. For example, as reported by van Delft et al., J. Vac. Sci. Technol. B, 18 (2000) 3419, a novolak-hydrido silsesquioxane (HSQ) bilayer stack was used to achieve 40 nm half-pitch resolution with an aspect ratio of 3.25:1 as well as isolated 40 nm lines with an aspect ratio of 20:1. However, fluorine-based etching of the underlying HSQ layer, resulted in swelling of the patterned novolak features, leading to wave-like distortions.

Therefore, there remains a need for a spin-on hard-mask material that withstands fluorine-based etching of underlying layers without distortion, so that high resolution patterns can be produced.

### BRIEF DESCRIPTION OF THE DRAWINGS

FIG. 1 illustrates the process for producing high aspect ratio, high resolution features using a spin-on hard-mask.

FIG. 2 illustrates the results of forming a hard-mask film with the materials described herein, heating the films and performing a solvent soak.

FIG. 3 shows 25 nm lines and spaces etched into about 100 nm of carbon according to the scheme set forth in FIG. 1.

### DETAILED DESCRIPTION OF THE DRAWINGS

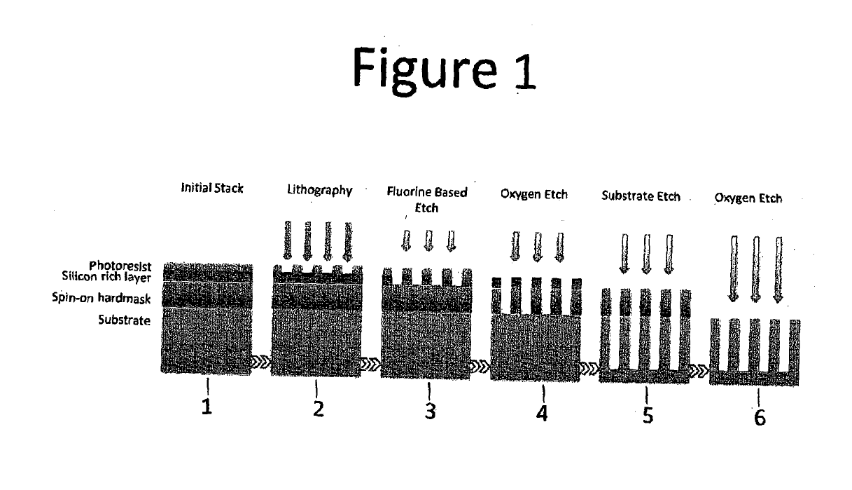

FIG. 1 shows a process for producing high aspect ratio, high resolution features using a spin-on hard-mask. In this embodiment, the initial stack 1 is a substrate; onto which has been coated a spin-on hard-mask, a silicon rich layer and a photoresist. The lithographic step 2 patterns the photoresist. In scheme 3, the patterned photoresist serves as an etch mask for the silicon rich layer, which, in turn serves as an etch mask for the underlying spin-on hard-mask layer 4. The hard-mask layer is then used as an etch mask for the substrate 5 and the silicon rich layer may be etched as depicted or may require a separate etch step. Finally, an oxygen etch is used to remove the spin-on hard-mask 6. The embodiment shown in FIG. 1 is but one example for illustration and is not intended to be limiting. For example, a photosensitive composition containing silicon may be employed instead of photoresist disposed on a silicon rich layer.

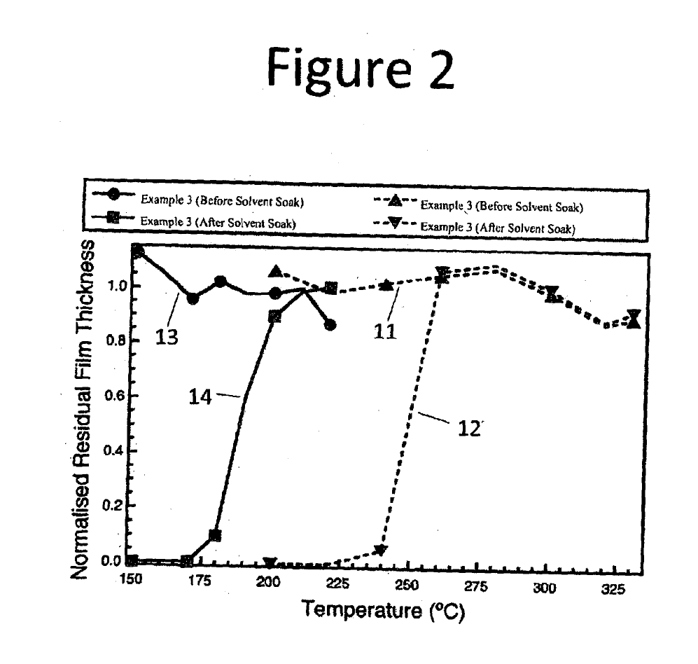

FIG. 2 shows results of forming a hard-mask film with the materials described herein, heating the films and performing a solvent soak. Specifically, the formulations from Example 2 and Example 3 (described infra) are spin coated onto a substrate and baked at various temperatures. Their thicknesses were compared before and after soaking in a chlorobenzene:isopropyl alcohol (1:1 w/w) solution. Turning to the films of Example 2, the normalized thickness of the film as baked at different temperatures, but not exposed to a solvent soak 11 is compared to the same films baked at different temperatures but exposed to the solvent soak 12. Turning to the films of Example 3, the normalized thickness of the film as baked at different temperatures, but not exposed to a solvent soak 13 is compared to the same films baked at different temperatures but exposed to the solvent soak 14.

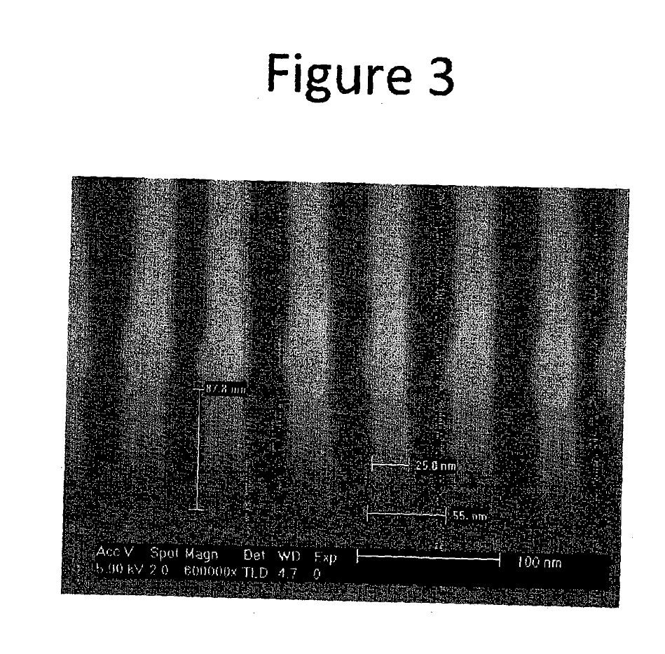

FIG. 3 shows 25 nm lines and spaces etched into about 100 nm of carbon according to the scheme set forth in FIG. 1. Details of the process used to form the image shown in FIG. 3 are provided infra.

### DETAILED DESCRIPTION

As used herein, the conjunction “and” is intended to be inclusive and the conjunction “or” is not intended to be exclusive unless otherwise indicated. For example, the phrase “or, alternatively” is intended to be exclusive. As used herein, an “alicyclic” compound is an organic compound that is both aliphatic and cyclic. Alicyclic compounds may contain one or more all-carbon rings which may be either saturated or unsaturated, but do not have aromatic character. Alicyclic compounds may or may not have aliphatic side chains attached. As used herein, the term “exemplary” is used to indicate an example and is not necessarily used to indicate preference.

Disclosed and claimed herein is composition for forming a spin-on hard-mask, comprising: a fullerene derivative, expressed by the general formula (I)

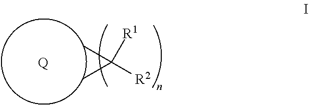

wherein n is an integer of 1-6, Q, the number of carbon atoms in the fullerene, is 60, 70, 76, 78, 80, 82, or 84, R¹ represents a first substituent comprising an ester, an alcohol, a phenol, an amine, an amide, an imide, or a carboxylic acid and R² represents a second substituent comprising hydrogen, a halogen, a C₆-C₂₀ aryl group, a C₁-C₂₀ alkyl group, an ester, an alcohol, a phenol, an amine, an amide, an imide, or a carboxylic acid; and a crosslinking agent comprising two or more thermally or catalytically reactive groups.

Further disclosed and claimed herein is A process for forming a spin-on hard-mask, comprising: providing a composition comprising (a) a fullerene derivative, expressed by the general formula (I), wherein n is an integer of 1-6, Q, the number of carbon atoms in the fullerene, is 60, 70, 76, 78, 80, 82, or 84, R¹ represents a first substituent comprising an ester, an alcohol, a phenol, an amine, an amide, an imide, or a carboxylic acid and R² represents a second substituent comprising hydrogen, a halogen, a C₆-C₂₀ aryl group, a C₁-C₂₀ alkyl group, an ester, an alcohol, a phenol, an amine, an amide, an imide, or a carboxylic acid; and (b) a crosslinking agent having two or more thermally or catalytically reactive groups; forming a coating on a substrate; and heating the substrate and the coating at a temperature sufficient to cross-link the coating.

Further disclosed and claimed herein, is a composition for forming a spin-on hard-mask, wherein the composition further comprises a thermal acid generator.

Further disclosed and claimed herein is a composition for forming a spin-on hard-mask, wherein the composition further comprises a photoacid generator.

Further disclosed and claimed herein is a composition for forming a spin-on hard-mask, wherein the composition further comprises a solvent such as polyethylene glycol monomethyl ether acetate, ethyl lactate, anisole, toluene, chloroform, chlorobenzene, o-dichloro benzene, m-dichloro benzene, p-dichloro benzene, o-xylene, m-xylene, p-xylene, carbon disulfide or combinations thereof

The general formula (I) is a representation of a derivatized fullerene molecule having 1-6 methano groups. Fullerenes can have different allotropes, including C₆₀, C₇₀, C₇₆, C₇₈, C₈₀, C₈₂, and C₈₄ as shown in (II), indicating the cage structure but not the bonding. In some cases, different allotropes may have the same number of carbons.

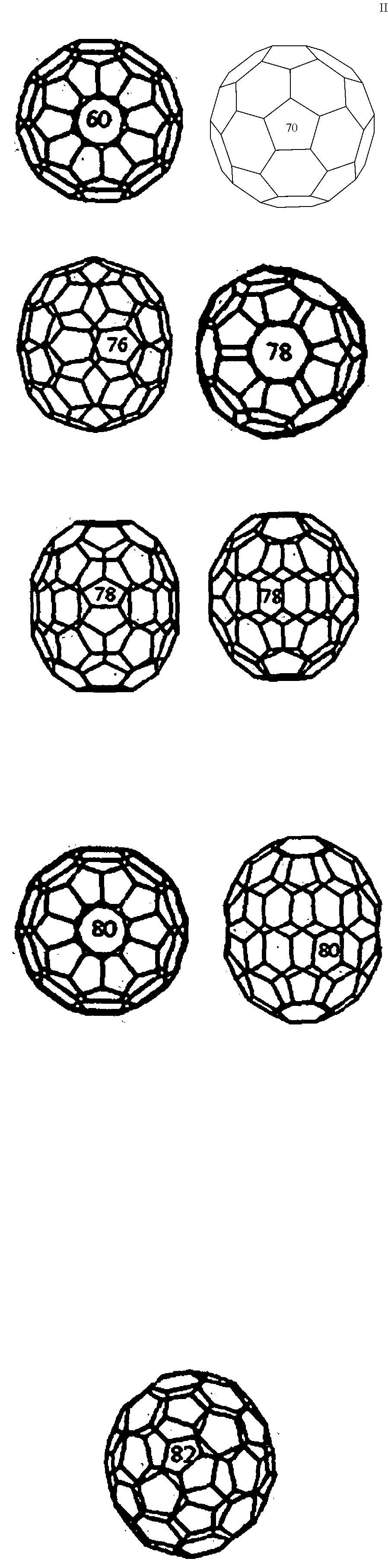 [SMILES: C1CC2C3CCC4C5CCC6C7CCC8C9CCC%10C1C1C2C2C3C4C3C5C6C4C7C8C5C9C%10C1C1C2C3C4C51]

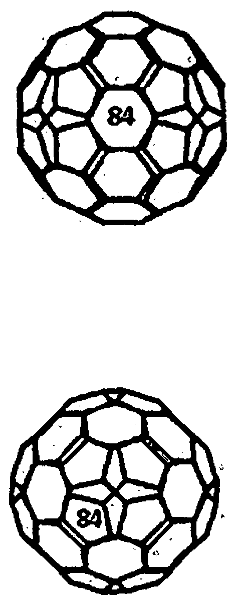

In accordance with the subject matter disclosed herein, fullerenes may be substituted across double bonds by a methano group to form a three-membered ring. In one embodiment, the methano group bridges across a vertex wherein two 6-membered rings meet to form a so-called [6, 6] bridge as shown in (III) (back carbons not shown). In another embodiment, a ring-opening [6, 5] substitution by the methano group may obtain to form a fulleroid structure. In some cases, however, the ring-opened [6, 5] fulleroid structure, may rearrange to a [6,6] bridged fullerene structure upon heating. Synthesis techniques for methanofullerenes are known in the art, such as in Fukashi et al., Beilstein J. Org. Chem. (2008), 4, No. 33. doi:10.3762/bjoc.4.33, and Hummelen et al., Org. Chem. (1995), 60, 532-538.

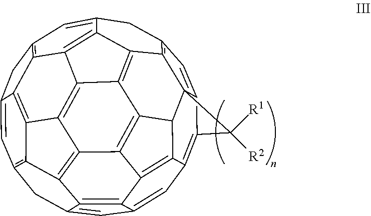

In accordance with the subject matter disclosed herein, the crosslinking agent may be chosen from an epoxidized phenolic novolak resin, an epoxidized cresylic novolak resin, an epoxidized bisphenol A resin, an epoxidized bisphenol novolak resin, an alkylolmethyl melamine resin, an alkylolmethyl glycoluril resin, an alkylolmethyl guanamine resin, an alkylomethyl benzo-guanamine resin, a glycosyl urea resin, or an isocyanate (alkyd) resin.

Suitable amine-based crosslinkers include the melamines manufactured by Cytec of West Paterson, N.J., such as CYMEL™ 300, 301, 303, 350, 370, 380, 1116 and 1130; benzoguanamine resins such as CYMEL™ 1123 and 1125; the glycoluril resins CYMEL™ 1170, 1171 and 1172; and the urea-based resins, BEETLE™ 60, 65 and 80, also available from Cytec, West Paterson, N.J. A large number of similar amine-based or amidoplast compounds are commercially available from various suppliers.

Epoxidized phenolic and cresylic novolak resins are shown in (IV), wherein X may be H, CH₃ and n may be 0-20. Epoxidized bisphenol A resins are shown in an idealized structure (V), wherein n may be 0-20. Epoxidized bisphenol Z resins are shown in an idealized structure (VI), wherein n may be 0-20. Similar “epoxidized bisphenol” crosslinking agents are contemplated. For example, resins based on the diglycidyl ethers of 1,1-bis(4-hydroxyphenyl)-1-phenyl-ethane, 2,2-bis(4-hydroxyphenyl)hexafluoropropane, 2,2-bis(4-hydroxyphenyl)butane, bis-(4-hydroxyphenyediphenylmethane, 2,2-bis(3-methyl-4-hydroxyphenyl)propane, bis(4-hydroxyphenyl)-2,2-dichlorethylene, 1,1-bis(4-hydroxyphenyl)ethane, bis(4-hydroxydiphenyl)methane, 2,2-bis(4-hydroxy-3-isopropyl-phenyl)propane, 1,3-bis(2-(4-hydroxyphenyl)-2-propyl)benzene, bis(4-hydroxyphenyl)sulfone, 1,4-bis(2-(4-hydroxyphenyl)-2-propyl)benzene, 5,5′-(1-methylethyliden)-bis[1,1-(bisphenyl)-2-ol]propane, 1,1-Bis(4-hydroyphenyl)-3,3,5-trimethyl-cyclohexane and

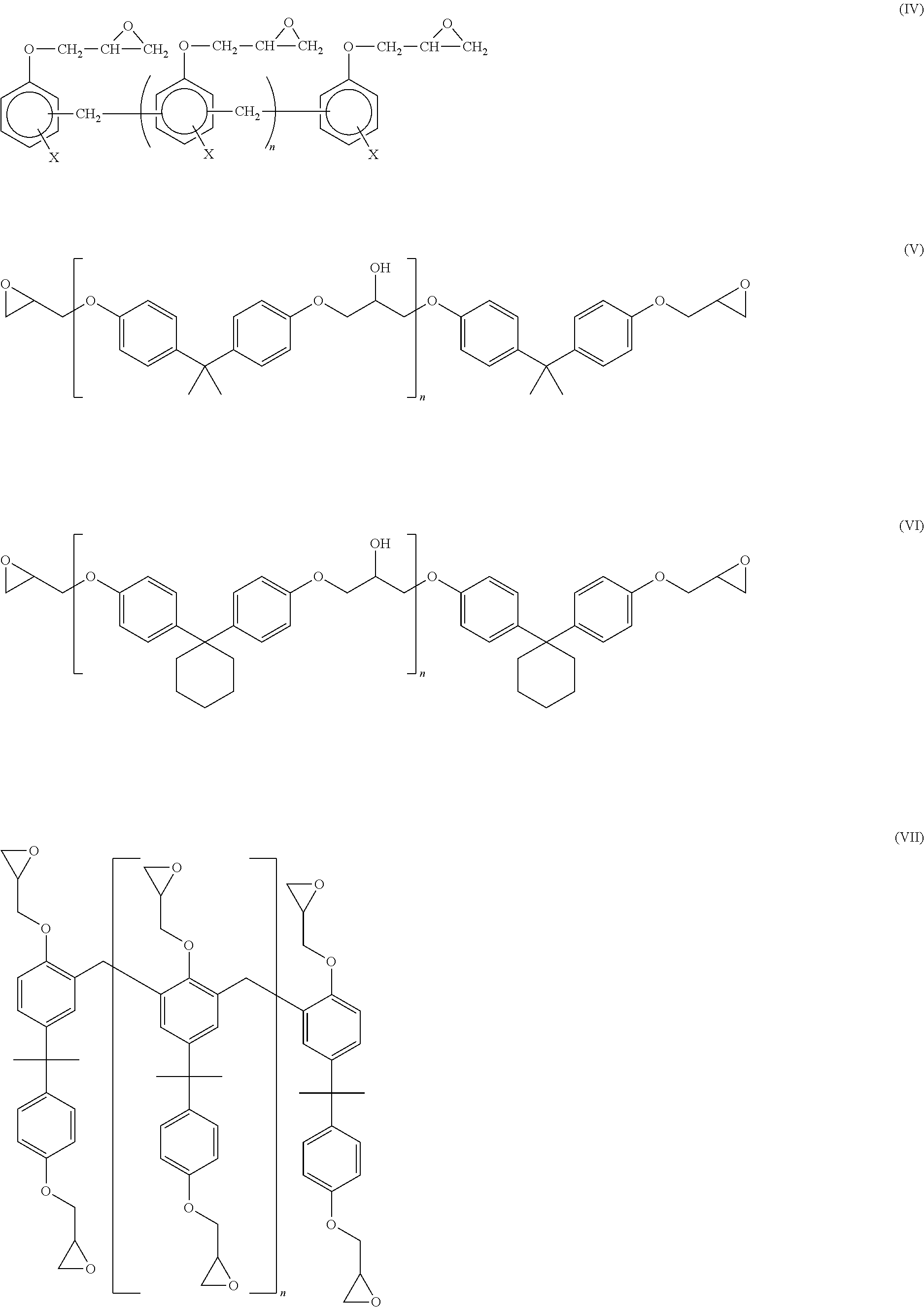

combinations with any of the foregoing may be used.

In accordance with the subject matter disclosed herein, suitable thermal acid generators may include alkyl esters of organic sulfonic acids, alicyclic esters of organic sulfonic acids, amine salts of organic sulfonic acids, 2-nitrobenzyl esters of organic sulfonic acids, 4-nitrobenzyl esters of organic sulfonic acids, benzoin esters of organic sulfonic acids, β-hydroxyalkyl esters of organic sulfonic acids, β-hydroxycycloalkyl esters of organic sulfonic acids, triaryl sulfonium salts of organic sulfonic acids, alkyl diaryl sulfonium salts of organic sulfonic acids, dialkyl aryl sulfonium salts of organic sulfonic acids, trialkyl sulfonium salts of organic sulfonic acids, diaryl iodonium salts of organic sulfonic acids, alkyl aryl sulfonium salts of organic sulfonic acids, or ammonium salts of tris(organosulfonyl) methides.

Onium salts comprise cations and anions. Exemplary cations of onium salts include triaryl sulfonium, alkyl diaryl sulfonium, dialkyl aryl sulfonium, trialkyl sulfonium, diaryl iodonium, alkyl aryl iodonium, dialkyl iodonium, triaryl selenonium, alkyl diaryl selenonium, dialkyl aryl selenonium, trialkyl selenonium. Without limitation, specific examples of cations in onium salts include triphenyl sulfonium, tri(p-tolyl) sulfonium, 1,4-phenylenebis(diphenylsulfonium) (having a charge of +2), diphenyliodonium, and bis(4-tert-butylphenyl)iodonium.

Further, without limitation, exemplary anions in onium salts include the halides, PF₆⁻, AsF₆⁻, SbF₆⁻, SbCl₆⁻, and BF₄⁻. In addition, without limitation, anions based on oxo-acids may be used. Among these are C₁-C₁₀ perfluoroalkane sulfonates such as trifluoro methane sulfonate, perfluoro butane sulfonate and perfluoro octane sulfonate, C₁-C₁₈ linear, branched and alicyclic alkane sulfonates, such as dodecane sulfonate, methane sulfonate and camphor sulfonate, C₁-C₁₈ aromatic and substituted aromatic sulfonates such as toluene sulfonate and dodecylbenzene sulfonate, C₁-C₁₈ fluorinated aryl sulfonates, such as the trifluoromethyl benzene sulfonates, pentafluoro benzene sulfonate and the like, C₁-C₁₈ carboxylates and halogenated carboxylates such as benzoate, acetate, chloroacetate, dichloroacetate, trichloroacetate, trifluoroacetate, perfluoropentanoate, pentafluoropropanoate, perfluorooctanoate, perfluorobenzoate, and the like. Further, without limitation, suitable anions include C₁-C₂₀ tris (alkane sulfonyl)methanides, tris (fluoralkane sulfonyl)methanides, (R₃C⁻), bis (alkane sulfonyl) imides, and bis (fluoroalkane sulfonyl) imides, (R₂N⁻), such as tris(trifluoromethylsulfonyl)methanide, bis(trifluoromethylsulfonyl)imide and the like. Further, without limitation, oxo-acid anions can be bound to polymers so that acid diffusion out of the hard-mask material can be limited. Among these are polymeric acids such as poly(vinyl sulfonate), poly(styrene-4-sulfonate), poly(tetrafluoroethylene-co-1,1,2,2-tetrafluoro-2-(1,2,2-trifluorovinyloxy)ethanesulfonate), poly((meth)acrylic acid) and the like. In addition, sulfonated and fluorosulfonated (meth)acrylic monomers may be incorporated into a variety of polymers. It will be appreciated that oxo-acid anions may comprise other elements such as Se, P, As, Sb to form selenonates, phosphonates, arsenonates, stibonates and the like. Thermal acid generators of the ester type may comprise, for example, any of the foregoing oxo-acid anions to form carboxylate, sulfonate, selenonate, phosphonate, arsenonate, and stibononate esters.

Further, without limitation, the ester-type and onium type thermal acid generators may be used as photoacid generators at wavelengths in which they absorb electromagnetic radiation of can act as electron acceptors from other components of the hard-mask composition. In addition, triazine-type photoacid generators may be used. Suitable halogenated triazines include halomethyl-s-triazines. Suitable halogenated triazines include for example, 2-[1-(3,4-benzodioxolyl)]-4,6-bis(trichloromethyl)-1,2,5-triazine, 2-[1-(2,3-benzodioxolyl)]-4,6-bis(trichloromethyl)-1,3,5-triazine, 2-[1-(3,4-benzodioxolyl)]-4,6-bis(tribromomethyl)-1,3,5-triazine, 2-[1-(2,3-benzodioxolyl)]-4,6-bis(tribromomethyl)-1,3,5-triazine, 2-(2-furfylethylidene)-4,6-bis(trichloromethyl)1,3,5-triazine, 2-[2-(5-methylfuryl)ethylidene]-4,6-bis(trichloromethyl)-1,3,5-triazine, 2-[2-(4-methylfuryl)ethylidene]-4,6-bis(trichloromethyl)-1,3,5-triazine, 2-[2-(3-methylfuryl)ethylidine]-4,6-bis-(trichloromethyl)-1,3,5-triazine, 2-[2-(4,5-dimethylfuryl)ethylidene]-4,6-bis(trichloromethyl)-1,3,5-triazine, 2-[2-(5-methoxyfuryl)ethylidene]-4,6-bis(trichloromethyl)-1,3,5-triazine, 2-[2-(4-methoxyfuryl)ethylidene]-4,6-bis(trichloromethyl)-1,3,5-triazine, 2-[2-(3-methoxyfuryl)ethylidene]-4,6-bis(trichloromethyl)-1,3,5-triazine, 2-[2-(4,5-dimethoxy-furyl)ethylidene]-4,6-bis(trichloromethyl)-1,3,5-triazine, 2-(2-(2-furyl)ethylidene)-4,6-bis(tribromomethyl)-1,3,5-triazine, 2-[2-(5-methylfuryl)ethylidene]-4,6-bis(tribromomethyl)-1,3,5-triazine, 2-[2-(4-methylfuryl)-ethylidene]-4,6-bis(tribromomethyl)-1,3,5-triazine, 2-[2-(3-methylfuryl)ethylidene]-4,6-bis(tribromomethyl)-1,3,5-triazine, 2-[2-(4,5-dimethoxyfuryl)ethylidene]-4,6-bis(tribromomethyl)-1,3,5-triazine, 2-[2-(5-methoxyfuryl)ethylidene]-4,6-bis(tribromomethyl)-1,3,5-triazine, 2-[2-(4-methoxyfuryl)ethylidene]-4,6-bis(tribromomethyl)-1,3,5-triazine, 2-[2-(3-methoxyfuryl)ethylidene]-4,6-bis(tribromomethyl)-1,3,5-triazine, 2-[2-(4,5-dimethoxyfuryl)ethylidene]-4,6-bis(tribromomethyl)-1,3,5-triazine, 2,4,6-tris-(trichloromethyl)-1,3,5-triazine, 2,4,6-tris-(tribromomethyl)-1,3,5-triazine, 2-phenyl-4,6-bis(trichloromethyl)-1,3,5-triazine, 2-phenyl-4,6-bis(tribromomethyl)-1,3,5-triazine, 2-(4-methoxyphenyl)-4,6-bis(trichloromethyl)-1,3,5-triazine, 2-(4-methoxyphenyl)-4,6-bis(tribromomethyl)-1,3,5-triazine, 2-(2-(1-naphthyl)-4,6-bis(trichloromethyl)-1,3,5-triazine, 2-(1-naphthyl)-4,6-bis(tribromomethyl)-1,3,5-triazine, 2-(4-methoxy-1-naphthyl)-4,6-bis(trichloromethyl)-1,3,5-triazine, 2-(4-methoxy-1-naphthyl)-4,6-bis(tribromomethyl)-1,3,5-triazline, 2-(4-chlorophenyl)-4,6-bis(tribromomethyl)-1,3,5-triazine, 2-styryl-4,6-bis(trichloromethyl)-1,3,5-triazine, 2-styryl-4,6-bis(tribromomethyl)-1,3,5-triazine, 2-(4-methoxystyryl)-4,6-bis(trichloromethyl)-1,3,5-triazine, 2-(4-methoxystyryl)-4,6-bis(tribromomethyl)-1,3,5-triazine, 2-(3,4,5-trimethoxystyryl)-4,6-bis(trichloromethyl)-1,3,5-triazine, 2(3,4,5-trimethoxystyryl)-4,6-bis(trichloromethyl)-1,3,5-triazine, 2-(3-chloro-1-phenyl)-4,6-bis(trichloromethyl)-1,3,5-triazine, 2-(3-chlorophenyl)-4,6-bis(tribromomethyl)-1,3,5-triazine and the like. Other triazine type photoacid generators useful in the present invention are disclosed in U.S. Pat. No. 5,366,846, herein incorporated by reference.

The s-triazine compounds are condensation reaction products of certain methyl-halomethyl-s-triazines and certain aldehydes or aldehyde derivatives. Such s-triazine compounds may be prepared according to the procedures disclosed in U.S. Pat. No. 3,954,475 and Wakabayashi et al., Bulletin of the Chemical Society of Japan, 42, 2924-30 (1969).

In accordance with the subject matter disclosed herein, the total solids in the claimed compositions may suitably comprise 1 g/l to 100 g/l. In accordance with the subject matter disclosed herein total solids in the claimed compositions may further suitably comprise 2.5 g/l to 75 g/l. In accordance with the subject matter disclosed herein total solids in the claimed compositions may still further suitably comprise 5 g/l to 50 g/l.

In accordance with the subject matter disclosed herein, the fullerene loading may suitably comprise 10% to 90% of the total solids in the composition. In accordance with the subject matter disclosed herein, the loading of the crosslinking agent may suitably comprise 90% to 10% of the total solids in the composition. In accordance with the subject matter disclosed herein, the loading of the thermal acid generator may suitably comprise 0% to 40% of the total solids in the composition. In accordance with the subject matter disclosed herein, the photoacid generator may suitably comprise 0% to 40% of the total solids in the composition. All percentages of solids composition are by weight.

Other materials may be present in the composition to enhance film forming characteristics. These include surfactants, wetting agents, rheology modifiers, antifoaming agents and the like.

In accordance with the subject matter disclosed herein, a film formed with any of the described compositions can be heated at a temperature sufficient to cause the crosslinking of the coated film. The presence of a thermal acid generator may lower the temperature at which crosslinking occurs. An exemplary temperature range may be from 80° C. to 350° C. Another exemplary temperature range may be from 100° C. to 250° C. Still another exemplary temperature range may be from 120° C. to 160° C.

In accordance with the subject matter disclosed herein, a film formed with any of the described compositions can be exposed to electromagnetic radiation at an exposure dose sufficient to cause the crosslinking of the coated film either during heating, before heating or at ambient temperature. The presence of a photoacid generator may lower the temperature at which crosslinking occurs. Exemplary exposure wavelengths may be 190 nm to 520 nm, depending on the sensitivity of the photoacid generator. Further exemplary exposure wavelengths may be 225 nm to 400 nm, depending on the sensitivity of the photoacid generator. An exemplary exposure dose range may be from 0.1 mJ/cm²-1000 mJ/cm². Another exemplary exposure dose range may be 1 mJ/cm² to 500 mJ/cm². Still another exemplary exposure dose range may be 10 mJ/cm² to 100 mJ/cm².

Without limitation, coating may suitably be accomplished by spray coating, blade coating, spin coating or combinations thereof. With regard to spin coating, for example, spin speeds may suitably range from 100 rpm to 8000 rpm. As a further example, spin speeds may suitably range from 200 rpm to 2000 rpm. As a still further example, spin speeds may range from 800 rpm to 1500 rpm. Spin times may suitably range from 10 sec to 150 sec. Substrates, coated by any of the above methods may suitably be softbaked before crosslinking. Suitable softbake temperatures may range from 50° C. to 150° C.

The following examples are illustrative and are not intended to limit the scope of the appended claims. For example, various substrates, methods of substrate preparation, etch chemistries and conditions, or resist types and exposure conditions may suitably be used.

### Example 1

### Substrate Preparation

Silicon (100) substrates (Rockwood Electronic Materials, n-type) were used for all experimental procedures. Square chips, 2 by 2 cm in size, were cut from a wafer using a Disco DAD 321 wafer dicer. The samples were cleaned using semiconductor grade chemicals from Riedel-de Haën. Samples were washed ultrasonically for 15 minutes in isopropyl alcohol (IPA), then rinsed for 1 minute in deionised (DI) water (Purite Neptune, 18.2 MΩ cm). A hydrogen terminated surface was then prepared by dipping the substrates in H₂SO₄ (95-98%):H₂O₂ for 10 minutes, DI water for 1 minute and dilute HF for 1 minute, followed by rinsing in DI water for a further minute before drying with nitrogen. Substrates were stored under vacuum after preparation and used within 2 days.

TABLE 1

| | | | Thermal | |
|---|---|---|---|---|
| | | | Acid | |
| | | Cross Linker, | Generator % | Composition |
| Example | Fullerene, % total solids | % total Solids | Total solids | Solids % |
| 2 | 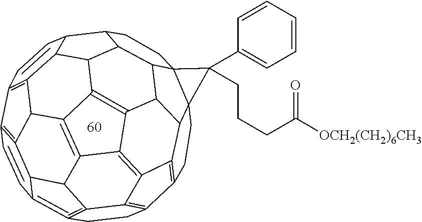 [6,6]-Phenyl-C61 butyric acid octyl ester (Nano-C Corp.), 50% of total solids | 50% | 0% | 7% |
| 3 | 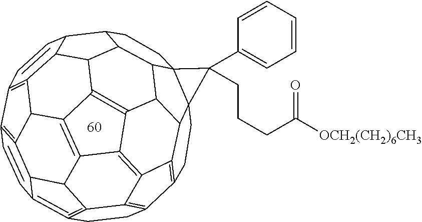 [6,6]-Phenyl-C61 butyric acid octyl ester (Nano-C Corp.), 40% of total solids | 40% | 20% | 7% |
| 4 | 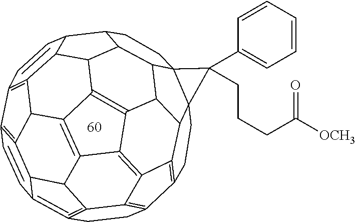 [6,6]-Phenyl-C61 butyric acid methyl ester (Nano-C Corp.), 50% of total solids | 50% | 0% | 7% |

### Examples 2-4

### Sample Preparation

Compositions for forming a spin-on hard-mask were prepared according to Table 1. The solvent used for all compositions was chloroform. The cross linking agent was Poly[(o-cresyl glycidyl ether)-co-formaldehyde], available from Sigma Aldrich company. The thermal acid generator was bis(tert-butyl phenyl) iodonium hexafluorophosphate, supplied by TCI Europe Ltd. Solids and the solvent were charged in a bottle and were dissolved quickly.

Films of the hard-mask were prepared by spin coating on the substrates of Example 1 at a spin speed of 1000 rpm for 60 sec, at a spin speed of 1000 rpm for the sample of Example 2, 1000 rpm for the sample of Example 3 and 1000 for the sample of Example 4. After spin coating the films were baked for five minutes at up to 330° C. After baking, Example 2 gave a film thickness of about 300 nm, Example 3 gave a film thickness of about 250 nm, Example 4 gave a film thickness of about 350 nm.

### Example 5

### Solubility Testing

In order to enable further processing, the spin-on hard-mask should be rendered insoluble in typical solvents for resist and further spin-on-hard-mask layers. FIG. 2 shows the normalized film thickness, spin coated from the formulations of Example 2 and Example 3, before and after dipping in monochlorobenzene (MCB):IPA 1:1 solution. For temperatures above 190° C. the film, spin coated from the formulation of Example 3, having a thermal acid generator, was rendered insoluble, while a temperature of 260° C. was required to achieve the same for the film spin coated from Example 2, which did not have a thermal acid generator.

### Example 6

### Producing an Etched Image

Films of the hard-mask material coated from the formulation of Example 2 were prepared by spin coating on the substrate of Example 1 with a spin speed of 1000 rpm and baked for 5 minutes at a temperature of 300° C. to produce a thickness of about 300 nm.

After preparation of a 300 nm hard-mask film, a 40 nm thick silicon layer was deposited by sputtering at an argon pressure of 1×10⁻² mbar for 2 minutes with 250 W RF power. Finally an electron beam resist, SAL 601™, available from Dow Electronic Materials Company, was spin coated on top of the silicon layer. The resist was patterned using an FEI XL30 SFEG scanning electron microscope equipped with a pattern generator (Raith Elphy Plus). 25 nm lines and spaces were patterned and then etched into the silicon thin film using an Oxford Instruments PlasmaPro NGP80 Inductively Coupled Plasma (ICP) etching system. Silicon substrates were attached using vacuum grease to a sacrificial silicon wafer to ensure good thermal contact. The sacrificial wafer was mechanically clamped to the lower electrode, which is equipped with helium backside pressure to ensure good thermal control of the sample during the etching process. The pattern was transferred into the silicon topcoat using a 20 second mixed mode SF₆/C₄F₈ ICP etch. SF₆ flow rate was 25 sccm and C₄F₈ flow rate 30 sccm. An RF power of 20 W and ICP power of 220 W were applied.

Transfer of the pattern from the silicon to the hard-mask was accomplished with an oxygen plasma etch was used. In order to minimize undercutting of the carbon, and maintain vertical sidewalls during the etch, at a chamber pressure of 1.5 mT was maintained. Etch duration was 20 seconds with an O₂ flow rate of 15 sccm. RF power of 100 W and ICP power of 300 W.

Finally, the hard-mask pattern was transferred into the silicon substrate with another mixed mode SF₆/C₄F₈ ICP etch, using an: SF₆ flow rate of 20 sccm, C₄F₈ flow rate 30 sccm, RF power 20 W, ICP power 220 W. FIG. 3 shows the result in which an aspect ratio of about 3.4 was obtained.

Although the present invention has been shown and described with reference to particular examples, various changes and modifications which are obvious to persons skilled in the art to which the invention pertains are deemed to lie within the spirit, scope and contemplation of the subject matter set forth in the appended claims.

1. A composition for forming a spin-on hard-mask, comprising:
a. a fullerene derivative, expressed by the general formula 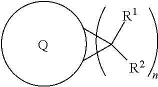
wherein n is an integer of 1-6, Q, the number of carbon atoms in the fullerene, is 60, 70, 76, 78, 80, 82, or 84, R¹ represents a first substituent comprising an ester, an alcohol, a phenol, an amine, an amide, an imide, or a carboxylic acid and R² represents a second substituent comprising hydrogen, a halogen, a C₆-C₂₀ aryl group, a C₁-C₂₀ alkyl group, an ester, an alcohol, a phenol, an amine, an amide, an imide, or a carboxylic acid.
b. a crosslinking agent comprising two or more thermally or catalytically reactive groups.

2. The composition of claim 1, further comprising one or more thermal acid generators.

3. The composition of claim 2, wherein the one or more thermal acid generators are chosen from alkyl esters of organic sulfonic acids, alicyclic esters of organic sulfonic acids, amine salts of organic sulfonic acids, 2-nitrobenzyl esters of organic sulfonic acids, 4-nitrobenzyl esters of organic sulfonic acids, benzoin esters of organic sulfonic acids, β-hydroxyalkyl esters of organic sulfonic acids, β-hydroxycycloalkyl esters of organic sulfonic acids, triaryl sulfonium salts of organic sulfonic acids, alkyl diaryl sulfonium salts of organic sulfonic acids, dialkyl aryl sulfonium salts of organic sulfonic acids, trialkyl sulfonium salts of organic sulfonic acids, diaryl iodonium salts of organic sulfonic acids, alkyl aryl sulfonium salts of organic sulfonic acids, or ammonium salts of tris(organosulfonyl) methides.

4. The composition of claim 2, further comprising one or more photoacid generators.

5. The composition of claim 4, wherein the one or more photoacid generators are chosen from halogenated triazines, 2-nitrobenzyl esters of organic sulfonic acids, 4-nitrobenzyl esters of organic sulfonic acids, triaryl sulfonium salts of organic sulfonic acids, alkyl diaryl sulfonium salts of organic sulfonic acids, dialkyl aryl sulfonium salts of organic sulfonic acids, diaryl iodonium salts of organic sulfonic acids, alkyl aryl sulfonium salts of organic sulfonic acids, n-organosulfonyloxybicyclo[2.2.1]-hept-5-ene-2,3-dicarboximides, or 1,3-dioxoisoindolin-2-yl organosulfonates.

6. The composition of claim 1, wherein the crosslinking agent is chosen from an epoxidized phenolic resin, an epoxidized cresylic resin, an epoxidized bisphenol A resin, an epoxidized bis-phenol A novolak resin, an epoxidized bisphenol resin, an alkylolmethyl melamine resin, an alkylolmethyl glycoluril resin, an alkylolmethyl guanamine resin, an alkylomethyl benzo-guanamine resin, a glycosyl urea resin, or an isocyanate resin.

7. The composition of claim 1, wherein the spin-on hard-mask further comprises one or more solvents chosen from polyethylene glycol monomethyl ether acetate, ethyl lactate, anisole, toluene, chloroform, chlorobenzene, o-dichloro benzene, m-dichloro benzene, p-dichloro benzene, o--xylene, m-xylene, p-xylene, carbon disulfide or combinations thereof.

8. A process for forming a spin-on hard-mask, comprising:
a. providing a composition comprising
i. a fullerene derivative, expressed by the general formula 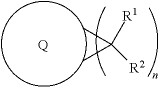
wherein n is an integer of 1-6, Q, the number of carbon atoms in the fullerene, is 60, 70, 76, 78, 80, 82, or 84, R¹ represents a first substituent comprising an ester, an alcohol, a phenol, an amine, an amide, an imide, or a carboxylic acid and R² represents a second substituent comprising hydrogen, a halogen, a C₆-C₂₀ aryl group, a C₁-C₂₀ alkyl group, an ester, an alcohol, a phenol, an amine, an amide, an imide, or a carboxylic acid; and
ii. a crosslinking agent having two or more thermally or catalytically reactive groups;
b. forming a coating on a substrate; and
c. heating the substrate and the coating at a temperature sufficient to cross-link the coating.

9. The process f claim 8, wherein the composition further comprises one or more thermal acid generators.

10. The process of claim 9, wherein the one or more thermal acid generators are chosen from alkyl esters of organic sulfonic acids, alicyclic esters of organic sulfonic acids, amine salts of organic sulfonic acids, 2-nitrobenzyl esters of organic sulfonic acids, 4-nitrobenzyl esters of organic sulfonic acids, benzoin esters of organic sulfonic acids, β-hydroxyalkyl esters of organic sulfonic acids, β-hydroxycycloalkyl esters of organic sulfonic acids, triaryl sulfonium salts of organic sulfonic acids, alkyl diaryl sulfonium salts of organic sulfonic acids, dialkyl aryl sulfonium salts of organic sulfonic acids, trialkyl sulfonium salts of organic sulfonic acids, diaryl iodonium salts of organic sulfonic acids, alkyl aryl sulfonium salts of organic sulfonic acids, or ammonium salts of tris(organosulfonyl) methides.

11. The process of claim 8, wherein the composition further comprises one or more photoacid generators.

12. The process of claim 11, wherein the one or more photoacid generators are chosen from halogenated triazines, 2-nitrobenzyl esters of organic sulfonic acids, 4-nitrobenzyl esters of organic sulfonic acids, triaryl sulfonium salts of organic sulfonic acids, alkyl diaryl sulfonium salts of organic sulfonic acids, dialkyl aryl sulfonium salts of organic sulfonic acids, diaryl iodonium salts of organic sulfonic acids, alkyl aryl sulfonium salts of organic sulfonic acids, n-organosulfonyloxybicyclo[2.2.1]-hept-5-ene-2,3-dicarboximides, or 1,3-dioxoisoindolin-2-yl organosulfonates.

13. The process of claim 8, wherein the crosslinking agent is chosen from an epoxidized phenolic resin, an epoxidized cresylic resin, an epoxidized bisphenol A resin, an epoxidized bis-phenol A novolak resin, an epoxidized bisphenol resin, an alkylolmethyl melamine resin, an alkylolmethyl glycoluril resin, an alkylolmethyl guanamine resin, an alkylomethy benzo-guanamine resin, a glycosyl urea resin, or an isocyanate resin.

14. The process of claim 8, wherein the composition further comprises one or more solvents chosen from polyethylene glycol monomethyl ether acetate, ethyl lactate, anisole, toluene, chloroform, chlorobenzene, o-dichloro benzene, m-dichloro benzene, p-dichloro benzene, o-xylene, m-xylene, p-xylene, carbon disulfide or combinations thereof.
